(19) United States
(12) Patent Application Publication
(10) Pub. No.: US 2023/0169230 A1
(43) Pub. Date: Jun. 1, 2023

(54) Probabilistic wind speed forecasting method and system based on multi-scale information

(71) Applicant: Central South University, Changsha (CN)

(72) Inventors: Yun Wang, Changsha (CN); Mengmeng Song, Changsha (CN); Runmin Zou, Changsha (CN); Daoguang He, Changsha (CN)

(21) Appl. No.: 17/902,946

(22) Filed: Sep. 5, 2022

(30) Foreign Application Priority Data
Dec. 1, 2021 (CN) 202111451691.3

(51) Int. Cl. G06F 30/20; G06Q 50/06

(52) U.S. Cl. CPC G06F 30/20; G06Q 50/06

(57) ABSTRACT

The invention provides a probabilistic wind speed forecasting method and system based on multi-scale information. First, a convolutional neural network (CNN) model with multiple convolutional layers is employed for extracting multi-scale features (MSFs). Then, an attention-based long short-term memory (LSTM) is utilized to extract temporal characteristics from the features at each scale and encode them into a low-dimensional feature vector. The difference between the conditional quantiles of adjacent quantiles is obtained with the proposed non-crossing quantile loss, and the estimates of all the conditional quantiles can be calculated by accumulating and subtracting. The proposed invention can extract sufficient MSFs from limited data, provide high-quality and reliable probabilistic forecasts, and solve the crossing problem of quantile-based models.

### TECHNICAL FIELD

The invention relates to the technical field of the development and utilization of renewable energy, and in particular, to a method and system for probabilistic wind speed forecasting based on multi-scale information.

### BACKGROUND

With the rapid development of the worldwide economy, the demand for energy continues to increase, which accelerates the depletion of non-renewable fossil energy. At the same time, the burning of fossil energy is always accompanied by the emission of a great deal of toxic substance and greenhouse gas, which seriously pollutes the ecological environment. Therefore, it is urgent to search for an alternative energy source. Wind energy, a clean and inexhaustible energy source, has attracted broad attention in recent years. However, the intermittency and randomness of wind brings difficulties to the large-scale grid integration of wind power. Accurate and effective wind power forecasting can meet this challenge. In addition, wind power forecasting also contributes to scientifically formulating dispatching plans, scheduling the spinning reserve capacity, reducing system operating costs, performing peak and frequency modulation work, maintaining the power balance of the system and arranging maintenance.

The current wind power forecasting methods can be divided into two groups: direct models and indirect models. The output of direct model is power forecasts. The indirect method first forecasts wind speed, and then obtain the power forecasts through a wind power curve. In the literature, there are many wind speed forecasting models, which can be divided into four categories: physical models, statistical models, artificial intelligence (AI)-based models and hybrid models.

Physical models make forecasting according to exhaustive physical description considering meteorological information and grids. Numerical weather prediction (NWP), a common physical model, outputs wind speed forecasts by solving equations reflecting atmospheric processes and how atmosphere varies over time. Physical models are only used for long-term wind speed forecasting because too much calculation and time are required. Statistical models usually use historical wind speed, as inputs without considering the meteorological data. Typical statistical models include autoregressive (AR), autoregressive moving average (ARMA), autoregressive integrated moving average (ARIMA) and fractional ARIMA (f-ARIMA). Statistical models can realize short-term forecasting and save computing, cost to a large extent, but they are good at characterizing linear relationship and have limited ability in analyzing highly nonlinear data such as wind speed series. AI-based models have superior ability in describing nonlinear fluctuations, thus have been widely used in forecasting wind energy. Popular AI-based models applied to wind energy forecasting include back propagation neural network (BPNN), Elman neural network, extreme learning machine (ELM), echo state network (ESN), general regression neural network (GRNN), radial basis function neural network (RBFNN), support vector machine (SVM), least square support vector machine (LSSVM) and deep learning (DL). Hybrid models is a combination of different types of forecasting models, it combines their advantages to improve forecasting accuracy.

The aforementioned methods all belong to deterministic forecasting, and their purpose is to provide forecasts that are close to the observed values. However, the uncertainty of the wind speed series will cause deviations between the forecast and the target. When deviation, information is not provided, planning and decision-making based on the deterministic forecasts with large errors will make the operation of power system risky. Thus, the probabilistic wind speed forecasting has attracted widespread attention. These probabilistic models can generate fluctuation intervals under different confidence levels or probability density curves to reflect the level of uncertainty. With the help of these methods, a comprehensive reference can be provided for the dispatch and operation of the power system. Generally, there are two kinds of probabilistic wind energy forecasting approaches: parametric models and non-parametric methods. Typical parametric models include the delta method, mean variance estimation (MVE) and Gaussian process regression (GPR). However, it is difficult to ensure that the wind speed strictly obeys a certain type of distribution. So, the parametric method lacks enough reliability. In contrast, the non-parametric method is distribution-free, which mainly includes the dower upper bound estimation (LUBE) and quantile regression (QR). QR can generate prediction intervals (PIs) under different PI nominal confidences (PINCs) by estimating conditional quantiles at multiple quantiles. In recent years, hybrid models based on AI models and quantile loss have been successively proposed, although they can greatly improve the forecasting performance, when the conditional quantiles at multiple quantiles need to be estimated, PIs estimated are usually crossed, which violates the monotonicity of different conditional quantiles.

Compared with the discrete PIs, probability density function (PDF) can provide more comprehensive, intuitive and detailed information. Kernel Density Estimation (KDE) is an effective technique for estimating PDF, with which multiple conditional quantiles can be converted into PDF without any assumptions about the shape of the distribution.

By reviewing the current studies, there are three shortages for the current forecasting models. First, insufficient features cannot characterize the strong intermittent and random natures of wind speed, resulting in bad forecasting performance. It has been proved in many studies that convolutional neural network (CNN) is an efficient feature extractor and helps enhance wind energy forecasting accuracy. In a multi-layer CNN, features obtained from different layers have information in different levels. However, only the features extracted from the last convolutional layer are used and multi-scale features (MSFs) of the remaining convolutional layers are ignored. As MSFs are not fully utilized, it may cause the loss of information and limits the forecasting performance of model. Second, the previous methods always focused on deterministic forecasting, but the reliability of forecasts cannot be guaranteed due to the existence of uncertainty. By contrast, probabilistic forecasting can quantify related uncertainties, whose, information provided is more reliable and comprehensive. In existing methods, QR is an effective strategy which can provide PIs under multiple PINCs. Third, QR is always accompanied by crossing problem, which limits the reliability of probabilistic forecasting results. However, this problem is always ignored in many previous studies.

### SUMMARY

The invention provides a probabilistic wind speed forecasting method and system based on multi-scale information. The proposed invention can extract sufficient MSFs from limited data, provide high-quality and reliable probabilistic forecasts, and solve the crossing problem of quantile-based models.

First, the invention provides a probabilistic wind speed forecasting method based on multi-scale information, which contains:

Step S1: Obtain historical wind speed data and divide it into a training set and a test set.

Step S2: Construct the neural network, which includes the MSF extraction module and attention-based LSTM. The MSF extraction module is used to extract one-dimensional (1D) feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting.

Step S3: Design loss function for training the neural network. First, determine the initial difference between the conditional quantiles of any two adjacent quantiles. Then, convert the initial difference into a set of positive differences of conditional quantiles through the approximate absolute-value conversion. Finally, determine the forecasts of the conditional quantiles for the remaining quantiles based on the conditional quantiles and the difference between the conditional quantiles of the two adjacent quantiles, and then the loss value can be computed based on the quantile loss function.

Step S4: Train the neural network with the training set, and then input the test set into the trained model to obtain the initial conditional quantile differences, which are converted to positive differences of the conditional quantiles through the approximate absolute-value conversion. By combining conditional quantiles at two different quantiles, PIs at a certain confidence level can be obtained. Meanwhile, the continuous probability density curve can be estimated with KDE based on all the acquired discrete conditional quantiles.

The Step S1 specifically includes:

Collect historical wind speed time series, and normalize them with:

$${x}_{normal} = \frac{x - {x}_{min}}{{x}_{max} - {x}_{min}} ,$$

where xₙₒᵣₘₐₗ is the normalized data, x represents the original wind speed series, and xₘₐₓ, xₘᵢₙ are the maximum and minimum of x, respectively.

The wind speed data is divided into, a training set and a test set according to a preset ratio, the training set is used for model training, and the test set, is used for testing the forecasting performance of the model.

In the Step S2, the MSF extraction module includes three stacked 1D convolutional layers. Each convolutional layer contains multiple kernels. The convolutional operation is defined as follows:

$${y}_{j}^{k} = f ( {b}_{j}^{k} + {\sum }_{h ∈ {M}_{j}} {w}_{hj}^{k - 1} * {x}_{h}^{k - 1} ) ,$$

where xₕ^{k-1} is the output of the h^{th} neuron at the (k−1)^{th} convolutional layer, Mⱼ is a set of input maps of the j^{th} neuron, bⱼ^{k} and yⱼ^{k} are the bias and output of the j^{th} neuron in the k^{th} convolutional layer, respectively, wₕⱼ^{k-1} is the weight matrix from the i^{th} neuron in the (k−1)^{th} convolutional layer to the j^{th} neuron in the k^{th} convolutional layer, ƒ(⋅) represents the activation function, and * denotes the convolution operation.

The 1D feature vectors generated by all the kernels of are concatenated in parallel to form a multi-dimensional feature subsequence. In this way, three subsequences {cⁱ}_{i=1,2,3} are obtained at this stage for each input.

In the Step S2, the attention-based LSTM module is specifically used to:

For each subsequence cⁱ, first, LSTM is used to extract temporal feature hⁱ={h₁ⁱ, h₂ⁱ, . . . , h_{L}_{ᵢ}ⁱ}, in which hⁱ is the hidden state of all the units in the i^{th} LSTM, Lᵢ denotes the number of the units. Then, convert hⁱ to h^{i′}={h₁^{i′}, h₂^{i′}, . . . , h_{L}_{ᵢ}^{i′}} through the fully connected layer. Finally, h^{i″}={h₁^{i″}, h₂^{i″}, . . . , h_{L}_{ᵢ}^{i″}} is obtained by adding h_{L}_{ᵢ}ⁱ to h^{i′}:

h^{i″}=h^{i′}+h_{L}_{ᵢ}ⁱ,

where h^{i″} is the new obtained feature vector, h^{i′} is the feature vector generated by the fully connected operation, and h_{L}_{ᵢ}ⁱ is the hidden state of the last unit in the i^{th} LSTM. Using the attention mechanism to assign weights for feature vectors in h^{i″}:

$${a}_{l}^{i} = \frac{exp ( {{h}_{{L}_{i}}^{i}}^{T} {h}_{l}^{{i}^{″}} )}{{\sum }_{k = 1}^{{L}_{i}} exp ( {{h}_{{L}_{i}}^{i}}^{T} {h}_{k}^{{i}^{″}} )} ,$$

in which hᵢ^{i″} and hₖ^{i″} are the l^{th} and k^{th} feature vector in h^{i″}, and aₗⁱ represents the attention probability for hₗ^{i″}. Afterwards, a low-dimensional feature vector is obtained by weighting the feature vectors in h^{i″} according to the derived attention probabilities:

$${v}^{i} = {\sum }_{l = 1}^{{L}_{i}} {a}_{l}^{i} {h}_{l}^{{i}^{″}} ,$$

where vⁱ represents the obtained feature vector for cⁱ. The final feature vector V is obtained by concatenating {vⁱ}_{i=1,2,3} together, which is used to generate forecasts through the fully connected layers.

For the quantile loss function, it is introduced as follows:

Q_{Y}(τ|X)=ƒ(X,β(τ)),

where Q_{Y}(τ|X) is the estimation at quantile r with the input X=(x₁, x₂, . . . , x_{N}), the target variables are Y=(y₁, y₂, . . . , y_{N}) ƒ(⋅) is a nonlinear function, and β(τ) represents the regression coefficients, which can be estimated by minimizing the loss function as follows:

$$\hat{β} ( τ ) = {min}_{β ( τ )} {\sum }_{i = 1}^{N} φ ( {y}_{i} , {Q}_{{y}_{i}} ( τ \vert {x}_{i} ) ) ,$$

where \hat{β}(τ) is the estimate of β(τ), N is the number of input samples, yᵢ is the targeted value that corresponds to the input xᵢ, Q_{y}_{ᵢ}(τ|xᵢ) is the conditional quantile at quantile τ, φ(⋅) is the quantile loss:

$$φ ( {y}_{i} , {Q}_{{y}_{i}} ( τ \vert {x}_{i} ) ) = \{ \begin{matrix}τ ( {y}_{i} - {Q}_{{y}_{i}} ( τ \vert {x}_{i} ) ) & {y}_{i} \geq {Q}_{{y}_{i}} ( τ \vert {x}_{i} ) \\ ( τ - 1 ) ( {y}_{i} - {Q}_{{y}_{i}} ( τ \vert {x}_{i} ) ) & {y}_{i} < {Q}_{{y}_{i}} ( τ \vert {x}_{i} )\end{matrix} .$$

The output of the conditional quantile \hat{Q}_{Y}(τ|xᵢ) includes the conditional quantile \hat{Q}_{Y}(τₖ_{₀}|X) at the middle quantile τₖ_{₀} and the initial difference between the conditional quantiles at any two adjacent quantiles Δ\hat{q}_{Y}(τ|xᵢ).

Supposing there are K quantiles τ={τₖ}_{k=1,2, . . . , K}, 0<τ₁<τ₂< . . . <τₖ_{₀}< . . . <τ_{K}<1, τₖ_{₀}=0.5,

$${\hat{Q}}_{Y} ( τ \vert X ) = {\{ {\hat{Q}}_{{y}_{i}} ( {τ}_{k} \vert {x}_{i} ) \}}_{k = 1 , 2 , … , K}^{i = 1 , 2 , … , N} ,$$

$${\hat{Q}}_{Y} ( {τ}_{{k}_{0}} \vert X ) = {\{ {\hat{Q}}_{{y}_{i}} ( {τ}_{{k}_{0}} \vert {x}_{i} ) \}}_{i = 1 , 2 , … , N} ,$$

$$Δ {\hat{q}}_{Y} ( τ \vert X ) = {\{ Δ {\hat{q}}_{{y}_{i}} ( {τ}_{k} \vert {x}_{i} ) \}}_{k = 1 , 2 , … , K - 1}^{i = 1 , 2 , … , N} .$$

A set of positive differences is obtained through the approximate absolute-value conversion with Δ\hat{q}_{Y}(τ|X), whose calculation is given by:

$$Δ {\hat{Q}}_{Y} ( τ \vert X ) = \{ \begin{matrix}Δ {\hat{q}}_{Y} ( τ \vert X ) & Δ {\hat{q}}_{Y} ( τ \vert X ) > 0 \\ θ & Δ {\hat{q}}_{Y} ( τ \vert X ) = 0 \\ - Δ {\hat{q}}_{Y} ( τ \vert X ) & Δ {\hat{q}}_{Y} ( τ \vert X ) < 0\end{matrix} , \#$$

where θ is a positive value,

$$Δ {\hat{Q}}_{Y} ( τ \vert X ) = {\{ Δ {\hat{Q}}_{{y}_{i}} ( {τ}_{k} \vert {x}_{i} ) \}}_{k = 1 , 2 , … , K - 1}^{i = 1 , 2 , … , N}$$

is the obtained positive difference between two adjacent conditional quantiles, and Δ\hat{Q}_{y}_{ᵢ}(τₖ|xᵢ)=\hat{Q}_{y}_{ᵢ}(τₖ₋₁|xᵢ)−\hat{Q}_{y}_{ᵢ}(τₖ|xᵢ).

Based on the obtained conditional quantile \hat{Q}_{Y}(τₖ_{₀}|X) and the conditional quantile difference Δ\hat{Q}_{Y}(τ|X), the estimates of all the conditional quantiles can be calculated by accumulating and subtracting from \hat{Q}_{Y}(τₖ_{₀}|X):

$${\hat{Q}}_{Y} ( {τ}_{k} \vert X ) = \{ \begin{matrix}{\hat{Q}}_{Y} ( {τ}_{{k}_{0}} \vert X ) + {\sum }_{j = {k}_{0}}^{k - 1} Δ {\hat{Q}}_{Y} ( {τ}_{j} \vert X ) & k > {k}_{0} \\ {\hat{Q}}_{Y} ( {τ}_{{k}_{0}} \vert X ) - {\sum }_{j = k}^{{k}_{0} - 1} Δ {\hat{Q}}_{Y} ( {τ}_{j} \vert X ) & k < {k}_{0}\end{matrix} ,$$

where \hat{Q}_{Y}(τₖ|X) is the estimate at quantile τₖ.

Finally, the total quantile loss used for model training can be computed as:

$$L = \frac{1}{N} {Σ}_{i = 1}^{N} {Σ}_{k = 1}^{K} φ ( {y}_{i} , {\hat{Q}}_{{y}_{i}} ( {τ}_{k} \vert {x}_{i} ) ) ,$$

where L represents the value of loss.

The probability density curve is estimated by:

$$\hat{f} ( z ) = \frac{1}{BK} {\sum }_{k = 1}^{K} {K}_{E} ( \frac{{\hat{Q}}_{{y}_{i}} ( {τ}_{k} \vert {x}_{i} ) - z}{B} ) ,$$

$${K}_{E} ( α ) = \{ \begin{matrix}\frac{3}{4} ( 1 - {α}^{2} ) & α ∈ [ - 1 , 1 ] \\ 0 & α ∉ [ - 1 , 1 ]\end{matrix} ,$$

in which \hat{ƒ}(z) is the obtained PDF, B is the bandwidth, and K_{E}(α) is the Epanechnikov kernel function.

Second, the invention provides a probabilistic wind speed forecasting system based on multi-scale information, which contains:

Data acquisition module. In this module, historical wind speed data are obtained and divided into a training set and a test set.

Model construction module. In this module, a neural network which includes an MSF extraction module and an attention-based LSTM module is constructed. The MSF extraction module is used to extract 1D feature vectors from input vector, which are then concatenated in parallel to form multiple sets of feature subsequences at different levels. The attention-based LSTM module is used to extract temporal information from the obtained feature subsequences. The local information in the temporal features is weighted to faun a low-dimensional feature vector to characterize the above feature subsequence. Finally, all low-dimensional feature vectors are concatenated to form a predictive feature vector for forecasting.

Loss function construction module. In this module, a quantile loss function is designed for training the neural network. First, determine the initial difference between the conditional quantiles at any two adjacent quantiles. Then, convert the initial difference into a set of positive differences of the conditional quantiles through the approximate absolute-value conversion. Finally, determine the forecasts of the conditional quantiles for the remaining quantiles based on the conditional quantiles and the difference between the conditional quantiles at the two adjacent quantiles, and then the loss value can be computed based on the quantile loss function.

Forecasting module. The neural network is trained with the training set, and then input the test set into the trained model to obtain the initial conditional quantile differences, which are converted to positive differences of the conditional quantiles through approximate absolute-value conversion. By combining the conditional quantiles at two different quantiles, PIs at a certain confidence level can be obtained. Meanwhile, the continuous probability density curve can be estimated with KDE based on all the acquired discrete conditional quantiles.

Third, the invention provides an electronic device that includes a memory, a processor, and a computer program which is stored in the memory and can run on the processor. The program executed on the processor implements the steps of the probabilistic wind speed forecasting method based on multi-scale information as described in the first aspect of the invention.

Fourth, the invention provides a non-transitory computer-readable storage medium with a computer program stored thereon. When the computer program is executed by the processor, it can implement the steps of the probabilistic wind speed forecasting method based on multi-scale information as claimed in the first aspect of the invention.

The invention provides a probabilistic wind speed forecasting method and system based on multi-scale information. First, a CNN model with multiple convolutional layers is employed for extracting MSFs. Then, an attention-based LSTM is utilized to extract temporal characteristics from the features at each scale and encode them into a low-dimensional feature vector. The difference between the conditional quantiles at adjacent quantiles is obtained with the proposed non-crossing quantile loss, and the estimates of all the conditional quantiles can be calculated by accumulating and subtracting. The proposed invention can extract sufficient MSFs from limited data, provide high-quality and reliable probabilistic forecasts, and solve the crossing problem of quantile-based models.

### BRIEF DESCRIPTION OF THE DRAWINGS

In order to explain the embodiments of the present invention or the technical solutions more clearly, the following, will briefly introduce the figures used in the description of the embodiments. Obviously, the figures in the following description are the embodiments of the present invention, and other drawings may be obtained in accordance with these figures, for those of ordinary skill in the same research field without creative labor.

FIG. 1 is the flowchart of the probabilistic wind speed forecasting method based on multi-scale information proposed by this invention.

FIG. 2 is a schematic diagram of the principle of the approximate absolute-value conversion.

FIG. 3 is a schematic diagram of the interval forecasting results of the model MSF-DNQR proposed by this invention on Dataset A and Dataset B.

FIG. 4 is a schematic diagram of the entity structure of this invention.

### DETAILED DESCRIPTION OF THE EMBODIMENTS

In order to make the objectives, technical solutions, and advantages of the invention clearer, the technical solutions in the embodiments of the invention will be described clearly and completely with reference to the attached figures. Obviously, the described embodiments are part of the embodiments of the invention. Based on the embodiments of the invention, all other embodiments obtained by those of ordinary skill in the same research field without creative work shall fall within the protection scope of the present invention.

The term “and/or” in the embodiment of the present invention is merely an association relationship describing associated objects, indicating that there can be three, types of relationships, for example, A and/or B, which can mean that A exists alone, and A and B exist at the same time, B alone exists.

The terms “first” and “second” in the embodiments of the present application are only used for descriptive purposes, and cannot be understood as indicating or implying relative importance or implicitly indicating the number of indicated technical features. Therefore, the features defined with “first” and “second” may explicitly or implicitly include at least one of the features. In the description of this application, the terms “include” and “have” and any variations thereof are intended to cover non-exclusive inclusion. For example, a system, product, or device that includes a series of components or units is not limited to the listed components or units, but alternatively includes unlisted components or units, or alternatively include other components or units inherent to these products or devices. In the description of the present application, “a plurality of” means at least two, such as two, three, etc., unless otherwise specifically defined.

Reference to “embodiments” herein means that a specific feature, structure, or characteristic described in conjunction with the embodiments may be included in at least one embodiment of the present application. The appearance of the phrase in various places in the specification does not necessarily refer to the same embodiment, nor is it an independent or alternative embodiment mutually exclusive with other embodiments. Those skilled in the art clearly and implicitly understand that the embodiments described herein can be combined with other embodiments.

There are three shortages for the current forecasting models. First, insufficient features cannot characterize the strong intermittent and random natures of wind speed, resulting in bad forecasting performance. It has been proved in many studies that CNN is an efficient feature extractor and helps enhance wind energy forecasting accuracy. In a multi-layer CNN, features obtained from different layers have information at different scales. However, only the features extracted from the last convolutional layer are used and MSFs of the remaining convolutional layers are ignored. As MSFs are not fully utilized, it may cause the loss of information and limit the forecasting performance of the model. Second, the previous methods always focused on deterministic forecasting, but the reliability of forecasts cannot be guaranteed due to the existence of uncertainty. By contrast, probabilistic forecasting can quantify related uncertainties, whose information provided is more reliable and comprehensive. In existing methods, OR is an effective strategy that can provide PIs under multiple PI nominal confidence levels (PINCs). Third, QR is always accompanied by crossing problem, which limits the reliability of probabilistic forecasting results. However, this problem is always ignored in many previous studies.

Therefore, the invention provides a probabilistic wind speed forecasting method and system based on multi-scale information, First, a CNN model with multiple convolutional layers is employed for extracting MSFs. Then, an attention-based LSTM is utilized to extract temporal characteristics from the features at each scale and encode them into a low-dimensional feature vector. The difference between the conditional quantiles at adjacent quantiles is obtained with the proposed non-crossing quantile loss, and the estimates of all the conditional quantiles can be calculated by accumulating and subtracting. The proposed invention can extract sufficient MSFs from limited data, provide high-quality and reliable probabilistic forecasts, and solve the crossing problem of quantile-based models.

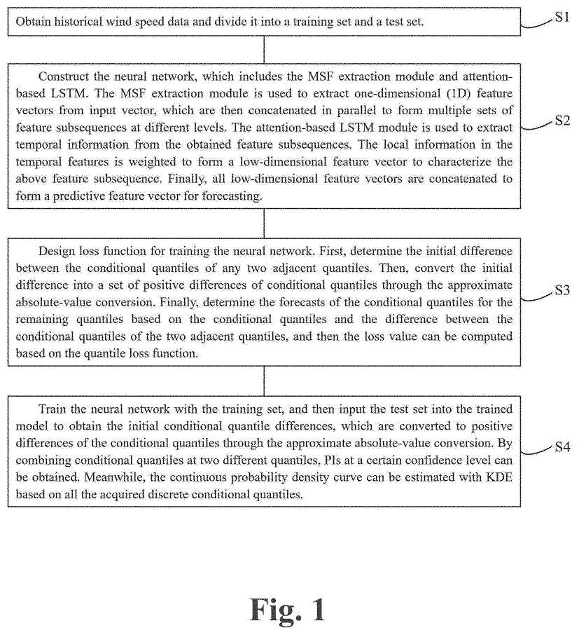

FIG. 1 provides a multi-scale information-based probabilistic wind speed forecasting method for the embodiment of this invention, including:

Step S1: Obtain historical wind speed data and divide it into a training set and a test set.

Collect historical wind speed time series, and normalize them with;

$${x}_{normal} = \frac{x - {x}_{min}}{{x}_{max} - {x}_{min}} , \qquad ( 1 )$$

where xₙₒᵣₘₐₗ is the normalized data, x represents the original wind speed series, and xₘₐₓ, xₘᵢₙ are the maximum and minimum of x, respectively.

The wind speed data is divided into a training set and a test set according to a preset ratio, the training set is used for model training, and the test set is used for testing the forecasting performance of the model.

Step 2: Construct the neural network, which includes the MSF extraction module and attention-based LSTM. The MSF extraction module is used to extract one-dimensional (1D) feature vectors from input vector, which are then concatenated in parallel to form multiple sets of feature subsequences at different levels. The attention-based LSTM module is used to extract temporal information from the obtained feature subsequences. The local information in the temporal features is weighted to form a low: dimensional feature vector to characterize the above feature subsequence. Finally, all low-dimensional feature vectors are concatenated to form a predictive feature vector for forecasting.

The model constructed in this invention is named as a deep non-crossing quantile regression model based on multi-scale features (MSF-DNQR), and the specific model implementation steps are as follows:

In a multi-layer CNN, features obtained from different layers have information at different scales. However, only the features extracted from the last convolutional layer are used and MSFs of the remaining convolutional layers are ignored. As MSFs are not fully utilized, it may cause the loss of information and limit the forecasting performance of the model. This invention designs an MSF extraction module to extract sufficient information from the limited data and compress it into low-dimensional feature vectors to reduce calculation costs. The processing steps of the module can be divided into the following two steps:

Step 2.1 MSF extraction. The MSF extraction module includes three stacked 1D convolutional layers. Each convolutional layer contains multiple kernels. The convolutional operation is defined as follows:

$${y}_{j}^{k} = f ( {b}_{j}^{k} + {\sum }_{h ∈ {M}_{j}} {w}_{h j}^{k - 1} * {x}_{h}^{k - 1} ) , \qquad ( 2 )$$

where xₕ^{k-1} is the output of the h^{th} neuron at the (k−1)^{th} convolutional layer, Mⱼ is a set of input maps of the j^{th} neuron, bⱼ^{k} and yⱼ^{k} are the bias and output of the j^{th} neuron in the k^{th} convolutional layer, respectively, wₕⱼ^{k-1} is the weight matrix from the i^{th} neuron in the (k−1)^{th} convolutional layer to the j^{th} neuron in the k^{th} convolutional layer, ƒ(⋅) represents the activation function, and * denotes the convolution operation.

The 1D feature vectors generated by all the kernels of are concatenated in parallel to form a multi-dimensional feature subsequence. In this way, three subsequences {cⁱ}_{i=1,2,3} are obtained at this stage for each input.

Step 2.2 Temporal feature extraction and encoding. For each subsequence cⁱ, first, LSTM is used to extract temporal feature hⁱ={h₁ⁱ, h₂ⁱ, . . . , h_{L}_{ᵢ}ⁱ}, in which hⁱ is the hidden state of all the units in the i^{th} LSTM, Lᵢ denotes the number of the units. Then, convert hⁱ to h^{i′}={h₁^{i′}, h₂^{i′}, . . . , h_{L}_{ᵢ}^{i′}} through the fully connected layer. Finally, h^{i″}={h₁^{i″}, h₂^{i″}, . . . , h_{L}_{ᵢ}^{i″}} is obtained by adding h_{L}_{ᵢ}ⁱ to h^{i′}:

h^{i″}=h^{i′}+h_{L}_{ᵢ}ⁱ, (3)

where h^{i″} is the new obtained feature vector, h^{i′} is the feature vector generated by the fully connected operation, and h_{L}_{ᵢ}ⁱ is the hidden state of the last unit in the i^{th} LSTM. Using the attention mechanism to assign weights for feature vectors in h^{i″}:

$${a}_{l}^{i} = \frac{exp ( {h}_{{L}_{i}}^{i} {}^{T} {h}_{l}^{{i}^{″}} )}{{Σ}_{k = 1}^{{L}_{i}} exp ( {h}_{{L}_{i}}^{i} {}^{T} {h}_{k}^{{i}^{″}} )} , \qquad ( 4 )$$

in which hᵢ^{i″} and hₖ^{i″} are the l^{th} and k^{th} feature vector in and represents the attention probability for hᵢ^{i″}. Afterwards, a low-dimensional feature vector is obtained by weighting the feature vectors in h^{i″} according to the derived attention probabilities:

$${v}^{i} = {\sum }_{l = 1}^{{L}_{i}} {a}_{l}^{i} {h}_{l}^{{i}^{″}} , \qquad ( 5 )$$

where vⁱ represents the obtained feature vector for cⁱ. The final feature vector V is obtained by concatenating {vⁱ}_{i=1,2,3} together, which is used to generate forecasts through the fully connected layers.

Step 3: Design a quantile loss function for training the neural network. First, determine the initial difference between the conditional quantiles of any two adjacent quantiles. Then, convert the initial difference into a set of positive differences of conditional quantiles through the approximate absolute-value conversion. Finally, determine the forecasts of the conditional quantiles for the remaining, quantiles based on the conditional quantiles and the difference between the conditional quantiles of the two adjacent quantiles, and then the loss value can be computed based on the quantile loss function.

The loss function constructed in this invention is a non-crossing quantile loss. Given input vectors X=(x₁, x₂, . . . , x_{N}) and the corresponding targets Y=(y₁, y₂, . . . , y_{N}), in which xᵢ∈ [symbol] ^{p}, yᵢ∈ [symbol] . QR is used to establish a mapping relationship between inputs and the forecasted target. AI models can be combined with quantile loss to deal with nonlinear problems:

Q_{Y}(τ|X)=ƒ(X,β(τ)), #(6).

where Q_{Y}(τ|X) is the estimation at quantile τ with the input X=(x₁, x₂, . . . x_{N}), the target variables are Y=(y₁, y₂, . . . , y_{N}), ƒ(⋅) is a nonlinear function, and β(τ) represents the regression coefficients, which can be estimated by minimizing the loss function as follows:

$$\hat{β} ( τ ) = {min}_{β ( τ )} {\sum }_{i = 1}^{N} φ ( {y}_{i} , {Q}_{{y}_{i}} ( τ \vert {x}_{i} ) ) , \qquad ( 7 )$$

where \hat{β}(τ) is the estimate of β(τ), N is the number of input samples, yᵢ is the targeted value that corresponds to the input xᵢ, Q_{y}_{ᵢ}(τ|xᵢ) is the conditional quantile at quantile τ, φ(∩) is the quantile loss:

$$φ ( {y}_{i} , {Q}_{{y}_{i}} ( τ \vert {x}_{i} ) ) = \{ \begin{matrix}τ ( {y}_{i} - {Q}_{{y}_{i}} ( τ \vert {x}_{i} ) ) & {y}_{i} \geq {Q}_{{y}_{i}} ( τ \vert {x}_{i} ) \\ ( τ - 1 ) ( {y}_{i} - {Q}_{{y}_{i}} ( τ \vert {x}_{i} ) ) & {y}_{i} < {Q}_{{y}_{i}} ( τ \vert {x}_{i} )\end{matrix} . \qquad ( 8 )$$

In order to construct multiple PIs and the PDF of the target variable, conditional quantiles at multiple quantiles need to be estimated. However, the obtained Ns always have the crossing problem, i.e., the estimate of the conditional quantile at quantile τ₁ is greater than or equal to the estimate of the conditional quantile at quantile τ₂ when 0<τ₁<τ₂<1. This phenomenon violates the monotonicity of the conditional quantile and makes the forecasting results unreliable. As a result, the present invention proposes a non-crossing quantile loss to solve the above problem. The process can be described as follows:

Supposing there are K quantiles τ={τₖ}_{k=1,2, . . . , K}, 0<τ₁<τ₂< . . . <τₖ_{₀}< . . . <τ_{K}<1, τₖ_{₀}=0.5 to estimate all conditional quantiles

$${\hat{Q}}_{Y} ( τ \vert X ) = {\{ {\hat{Q}}_{{y}_{i}} ( {τ}_{k} \vert {x}_{i} ) \}}_{k = 1 , 2 , … , K}^{i = 1 , 2 , … , N}$$

simultaneously, the conditional quantile \hat{Q}_{Y}(τₖ_{₀}|X)={\hat{Q}_{y}_{ᵢ}(τₖ_{₀}|xᵢ)}_{i=1,2, . . . , N} at the middle quantile τₖ_{₀} and the initial difference

$$Δ {\hat{q}}_{Y} ( τ \vert X ) = {\{ Δ {\hat{q}}_{{y}_{i}} ( {τ}_{k} \vert {x}_{i} ) \}}_{k = 1 , 2 , … , K - 1}^{i = 1 , 2 , … , N}$$

between the conditional quantiles at any two adjacent quantiles are needed.

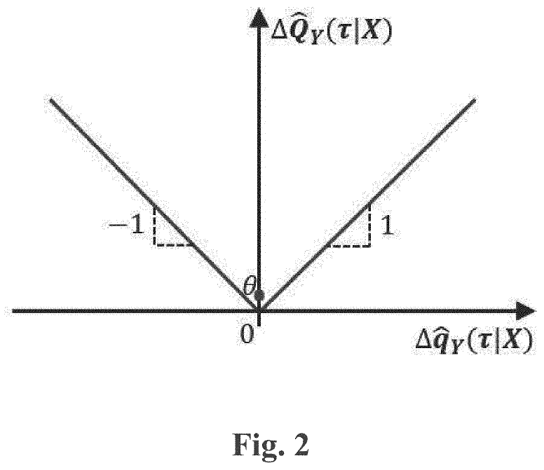

As shown in FIG. 2, based on Δ\hat{q}_{Y}(τ|X), a set of positive differences of the conditional quantiles can be obtained by approximate absolute-value conversion, whose calculation is given by:

$$Δ {\hat{Q}}_{Y} ( τ \vert X ) = \{ \begin{matrix}Δ {\hat{q}}_{Y} ( τ \vert X ) & Δ {\hat{q}}_{Y} ( τ \vert X ) > 0 \\ θ & Δ {\hat{q}}_{Y} ( τ \vert X ) = 0 \\ - Δ {\hat{q}}_{Y} ( τ \vert X ) & Δ {\hat{q}}_{Y} ( τ \vert X ) < 0\end{matrix} , \qquad \# ( 9 )$$

where θ is a positive value,

$$Δ {\hat{Q}}_{Y} ( τ \vert X ) = {\{ Δ {\hat{Q}}_{{y}_{i}} ( {τ}_{k} \vert {x}_{i} ) \}}_{k = 1 , 2 , … , K - 1}^{i = 1 , 2 , … , N}$$

is the obtained positive difference between two adjacent conditional quantiles, and Δ\ddot{Q}_{y}_{ᵢ}(τₖ|xᵢ)=\hat{Q}_{y}_{ᵢ}(τₖ₊₁|xᵢ)−\hat{Q}_{y}_{ᵢ}(τₖ|xᵢ).

Based on the obtained conditional quantile \hat{Q}_{Y}(τₖ_{₀}|X) and the conditional quantile difference \hat{Q}_{Y}(τ|X), the estimates of all the conditional quantiles can be calculated by accumulating and subtracting from \hat{Q}_{Y}(τₖ_{₀}|X):

$${\hat{Q}}_{Y} ( {τ}_{k} \vert X ) = \{ \begin{matrix}{\hat{Q}}_{Y} ( {τ}_{{k}_{0}} \vert X ) + {{\sum }_{j = {k}_{0}}}^{k - 1} Δ {\hat{Q}}_{Y} ( {τ}_{j} \vert X ) & k > {k}_{0} \\ {\hat{Q}}_{Y} ( {τ}_{{k}_{0}} \vert X ) - {{\sum }_{j = k}}^{{k}_{0} - 1} Δ {\hat{Q}}_{Y} ( {τ}_{j} \vert X ) & k < {k}_{0}\end{matrix} , \qquad ( 10 )$$

where \hat{Q}_{Y}(τₖ_{₀}|X) is the estimate at quantile τₖ.

Finally, the total quantile loss used for model training can be computed as:

$$L = \frac{1}{N} {\sum }_{i = 1}^{N} {\sum }_{k = 1}^{K} φ ( {y}_{i} , {\hat{Q}}_{{y}_{i}} ( {τ}_{k} \vert {x}_{i} ) ) , \qquad ( 11 )$$

where L represents the value of loss. Since the differences of the conditional quantile at two adjacent quantiles are positive, the conditional quantiles at different quantiles are monotonically increasing and the crossing problem is eliminated.

Step S4: Train the neural network with the training set, and then input the test set into the trained model to obtain the initial conditional quantile differences, which are converted to positive differences of the conditional quantiles through approximate absolute value conversion. By combining conditional quantiles at two different quantiles, PIs at a certain confidence level can be obtained. Meanwhile, the continuous probability density curve can be estimated with KDE based on all the acquired discrete conditional quantiles.

When a test sample is fed into the trained model, the corresponding output vector ƒₙₒᵣₘₐₗ is anti-normalized to obtain the final forecasts:

ƒ=ƒₙₒᵣₘₐₗ·(xₘₐₓ−xₘᵢₙ)+xₘᵢₙ, (12)

where ƒ is the final forecast vector, which is then converted into the conditional quantiles at all the given quantiles according to Eq. (9) and Eq. (10). By combining the conditional quantiles at two different quantiles, PIs at a certain confidence level can be obtained. Meanwhile, the continuous probability density curve can be estimated with KDE based on all the acquired discrete conditional quantiles to intuitively reflect the uncertainty. The probability density curve is estimated by:

$$\hat{f} ( z ) = \frac{1}{BK} {\sum }_{k = 1}^{K} {K}_{E} ( \frac{{\hat{Q}}_{{y}_{i}} ( {τ}_{k} \vert {x}_{i} ) - z}{B} ) , \qquad ( 13 )$$

$${K}_{E} ( α ) = \{ \begin{matrix}\frac{3}{4} ( 1 - {α}^{2} ) & α ∈ [ - 1 , 1 ] \\ 0 & α ∉ [ - 1 , 1 ]\end{matrix} , \qquad ( 14 )$$

in which \hat{ƒ}(z) is the obtained PDF, B is the bandwidth, and K_{E}(α) is the Epanechnikov kernel function.

Through the above operations, it is possible to extract and make full use of MSFs from the limited data, obtain multiple PIs and continuous probability density curves, and, solve the crossing problem at the same time.

In order to verify the reliability of the embodiments of the invention, two wind speed datasets from South Dakota are used to evaluate the effectiveness of the proposed model. The two datasets are collected throughout 2012 (from Jan. 1, 2012 to Dec. 31, 2012) with the time resolution of 1 hour. Each dataset is divided into two sets: training set and test set. The training set consists of the data points of the first eight months, which is used to train different forecasting models, and the test set with the data points of the remaining four months is used to test the forecasting performance of different models. For the convenience of description, the two datasets are named Dataset A and Dataset B, respectively. In order to evaluate the forecasting performance of different models, 7 metrics are used, i.e., prediction interval coverage probability (PICP), average coverage error (ACE), prediction interval normalized average width (PINAW), mean prediction interval width (MPIW), coverage width-based criterion (CWC), interval score (IS), and Pinball loss (PL).

To evaluate the probabilistic forecasting performance of the proposed model, multiple probabilistic forecasting methods are select as benchmark models in this invention, which can be divided into traditional models and artificial intelligence (AI)-based models. The traditional models include GPR, linear quantile regression (LQR). The AI-based models include LUBE and quantile-based models. The LUBE can simultaneously generate upper and lower bounds of the PIs for the given PINC. The AI-based quantile loss model generates conditional quantile of the target variable by combining artificial intelligence techniques with quantile loss. The popular models include quantile-based CNN (QR-CNN), quantile-based LSTM (QR-LSTM), quantile-based neural network (QR-NN), quantile-based CNN-LSTM

(QR-CNN-LSTM). In order to verify the performance of the proposed MSF module, the loss function of the quantile-based models should be consistent to make comparison fair, so a model named MSF-DQR is additionally added, which combined the MSF module and the traditional quantile loss function.

The parameter settings of the benchmark models follow the relevant literature, and the Adam optimizer is used to tune the deep learning-based models. This invention selects 199 quantiles with an equal interval from 0.005 to 0.995. The number of input nodes and the length of input sequence are set as 12. Furthermore, in the proposed loss function, θ is set as 1×10⁻⁸. In order to illustrate the probabilistic wind speed forecasting performance of the proposed model, this invention compares the PIs generated by the different models at 85%, 90%, and 95% confidence levels. The forecasting results are shown in Table 1 and Table 2.

TABLE 1
Probabilistic forecasting results of different methods on Dataset A.

| PIN | Method | PICP | ACE | MPI | PINA | CWC | IS | PL |
|---|---|---|---|---|---|---|---|---|
| 85% | GPR | 0.892 | 0.0427 | 3.447 | 0.1464 | 0.146 | −1.553 | 0.194 |
| | LUBE | 0.936 | 0.0866 | 5.408 | 0.2297 | 0.229 | −1.325 | 0.165 |
| | LQR | 0.892 | 0.0423 | 3.219 | 0.1367 | 0.136 | −1.325 | 0.165 |
| | QR-NN | 0.882 | 0.0320 | 3.182 | 0.1352 | 0.135 | −1.333 | 0.166 |
| | QR-CNN | 0.877 | 0.0279 | 2.818 | 0.1197 | 0.119 | −1.225 | 0.153 |
| | QR-LSTM | 0.898 | 0.0488 | 3.238 | 0.1375 | 0.137 | −1.314 | 0.164 |
| | QR-CNN-LST | 0.888 | 0.0385 | 3.145 | 0.1336 | 0.133 | −1.322 | 0.165 |
| | MSF-DQR | 0.862 | 0.0121 | 2.674 | 0.1136 | 0.113 | −1.178 | 0.147 |
| | MSF-DNQR | 0.862 | 0.0121 | 2.689 | 0.1142 | 0.114 | −1.183 | 0.148 |
| 90% | GPR | 0.924 | 0.0242 | 3.925 | 0.1667 | 0.166 | −1.208 | 0.151 |
| | LUBE | 0.950 | 0.0506 | 5.430 | 0.2306 | 0.230 | −1.296 | 0.162 |
| | LQR | 0.934 | 0.0342 | 3.942 | 0.1674 | 0.167 | −1.032 | 0.129 |
| | QR-NN | 0.923 | 0.0235 | 3.912 | 0.1661 | 0.166 | −1.052 | 0.131 |
| | QR-CNN | 0.920 | 0.0208 | 3.465 | 0.1471 | 0.147 | −0.954 | 0.119 |
| | QR-LSTM | 0.929 | 0.0290 | 3.912 | 0.1661 | 0.166 | −1.022 | 0.127 |
| | QR-CNN-LST | 0.924 | 0.0242 | 3.818 | 0.1622 | 0.162 | −1.039 | 0.129 |
| | MSF-DQR | 0.913 | 0.0132 | 3.222 | 0.1368 | 0.136 | −0.908 | 0.113 |
| | MSF-DNQR | 0.911 | 0.0115 | 3.253 | 0.1382 | 0.138 | −0.907 | 0.113 |
| 95% | GPR | 0.947 | −0.002 | 4.691 | 0.1992 | 0.309 | −0.780 | 0.097 |
| | LUBE | 0.964 | 0.0143 | 6.108 | 0.2594 | 0.259 | −0.754 | 0.094 |
| | LQR | 0.963 | 0.0130 | 5.134 | 0.2180 | 0.218 | −0.649 | 0.081 |
| | QR-NN | 0.957 | 0.0078 | 5.093 | 0.2163 | 0.216 | −0.661 | 0.082 |
| | QR-CNN | 0.961 | 0.0112 | 4.532 | 0.1925 | 0.192 | −0.594 | 0.074 |
| | QR-LSTM | 0.967 | 0.0171 | 5.262 | 0.2235 | 0.223 | −0.648 | 0.081 |
| | QR-CNN-LST | 0.960 | 0.0102 | 5.052 | 0.2146 | 0.214 | −0.674 | 0.084 |
| | MSF-DQR | 0.956 | 0.0061 | 4.206 | 0.1786 | 0.178 | −0.567 | 0.070 |
| | MSF-DNQR | 0.962 | 0.0126 | 4.344 | 0.1845 | 0.184 | −0.569 | 0.071 |

TABLE 2
Probabilistic forecasting results of different methods on Dataset B.

| PIN | Method | PICP | ACE | MPI | PINA | CWC | IS | PL |
|---|---|---|---|---|---|---|---|---|
| 85% | GPR | 0.908 | 0.058 | 3.404 | 0.1688 | 0.168 | −1.319 | 0.164 |
| | LUBE | 0.914 | 0.064 | 4.602 | 0.2282 | 0.228 | −1.701 | 0.212 |
| | LQR | 0.879 | 0.029 | 3.031 | 0.1504 | 0.150 | −1.284 | 0.160 |
| | QR-NN | 0.867 | 0.017 | 2.999 | 0.1488 | 0.148 | −1.302 | 0.162 |
| | QR-CNN | 0.870 | 0.020 | 2.762 | 0.1370 | 0.137 | −1.196 | 0.149 |
| | QR-LSTM | 0.885 | 0.035 | 3.023 | 0.1500 | 0.150 | −1.266 | 0.158 |
| | QR-CNN-LST | 0.862 | 0.012 | 2.726 | 0.1352 | 0.135 | −1.216 | 0.152 |
| | MSF-DQR | 0.870 | 0.020 | 2.664 | 0.1322 | 0.132 | −1.156 | 0.144 |
| | MSF-DNQR | 0.857 | 0.007 | 2.537 | 0.1258 | 0.125 | −1.153 | 0.144 |
| 90% | GPR | 0.933 | 0.033 | 3.877 | 0.1923 | 0.192 | −0.996 | 0.124 |
| | LUBE | 0.952 | 0.052 | 5.181 | 0.2570 | 0.257 | −1.232 | 0.154 |
| | LQR | 0.927 | 0.027 | 3.722 | 0.1846 | 0.184 | −0.997 | 0.124 |
| | QR-NN | 0.919 | 0.019 | 3.721 | 0.1846 | 0.184 | −1.004 | 0.125 |
| | QR-CNN | 0.911 | 0.011 | 3.330 | 0.1652 | 0.165 | −0.918 | 0.114 |
| | QR-LSTM | 0.925 | 0.025 | 3.701 | 0.1836 | 0.183 | −0.979 | 0.122 |
| | QR-CNN-LST | 0.915 | 0.015 | 3.346 | 0.1660 | 0.166 | −0.948 | 0.118 |
| | MSF-DQR | 0.915 | 0.015 | 3.191 | 0.1583 | 0.158 | −0.891 | 0.111 |
| | MSF-DNQR | 0.906 | 0.006 | 3.071 | 0.1523 | 0.152 | −0.887 | 0.110 |
| 95% | GPR | 0.963 | 0.013 | 4.633 | 0.2298 | 0.229 | −0.607 | 0.075 |
| | LUBE | 0.968 | 0.018 | 5.994 | 0.2973 | 0.297 | −0.721 | 0.090 |
| | LQR | 0.964 | 0.014 | 4.935 | 0.2448 | 0.244 | −0.633 | 0.079 |
| | QR-NN | 0.958 | 0.008 | 5.004 | 0.2482 | 0.248 | −0.653 | 0.081 |
| | QR-CNN | 0.961 | 0.011 | 4.439 | 0.2202 | 0.220 | −0.578 | 0.072 |
| | QR-LSTM | 0.965 | 0.015 | 4.982 | 0.2471 | 0.247 | −0.617 | 0.077 |
| | QR-CNN-LST | 0.960 | 0.010 | 4.475 | 0.2220 | 0.222 | −0.587 | 0.073 |
| | MSF-DQR | 0.958 | 0.008 | 4.180 | 0.2073 | 0.207 | −0.554 | 0.069 |
| | MSF-DNQR | 0.955 | 0.005 | 4.079 | 0.2023 | 0.202 | −0.555 | 0.069 |

First, by comparing the forecasting performance of GPR LUBE, LQR, QR-NN, QR-CNN, QR-LSTM, QR-CNN-LSTM, MSF-DQR on different datasets at different confidence levels, it can be seen that the proposed model MSF-DQR performs better than the other benchmark models. Deep learning models except for LUBE are better than the traditional probabilistic forecasting models, e.g., GPR and LQR. The quantile loss-based deep learning models perform better than LUBE. Among the quantile-based benchmark models, QR-CNN has the best performance, but it is still not as good as MSF-DQR that is based on MSF extraction. Since QR-NN, QR-CNN, QR-LSTM, QR-CNN-LSTM, MSF-DQR have the same loss function, if enough MSFs are, extracted and used, forecasting performance may be, enhanced.

Second, by comparing the forecasting results of MSF-DQR and MSF-DNQR, it can be found that they have similar forecasting performance. Since they have the same model structure, MSF-DNQR only improves the loss function compared with MSF-DQR. The above phenomenon indicates that the introduction of no-crossing quantile loss has no negative effect on the forecasting performance of the model.

MSF-DNQR is superior to other benchmark models in terms of reliability (PICP, ACE), sharpness (MPIW, PINAW), comprehensive index (CWC, IS) and accuracy (PL) except MSF-DQR. Therefore, the proposed model can generate probabilistic forecasts with higher quality and accuracy.

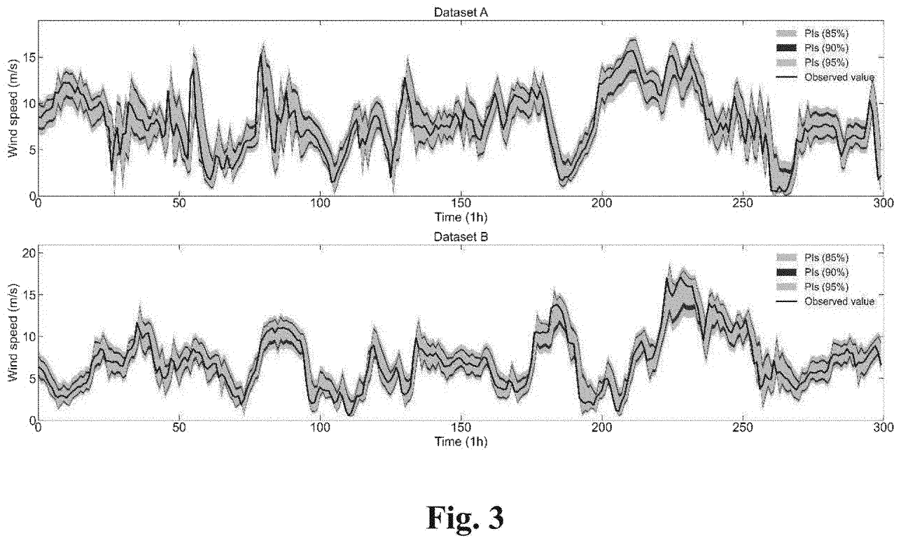

FIG. 3 presents the wind speed PIs of MSF-DNQR at 85%, 90%, and 95% confidence levels. It can be observed that the upper and lower bounds fluctuate up and down with the observed value. The PIs cover most of the observed values while keeping a narrow width, which indicates that MSF-DNQR, can provide reliable and high-quality wind speed PIs.

In order to convert the outputs of the neural network into positive difference between conditional quantiles of two adjacent quantiles, in addition to the strategy shown in Eq. (9), several other strategies based on sofmax, softplus and ReLU activation functions are also proposed, which are defined as Eq. (15), Eq. (16) and Eq. (17), respectively.

$$Δ {\hat{Q}}_{Y} ( τ \vert X ) = \frac{{e}^{Δ {\hat{q}}_{Y}} ( τ \vert X )}{{\sum }_{k = 1}^{K - 1} {e}^{Δ {\hat{q}}_{Y} ( {τ}_{k} \vert X )}} , \qquad \# ( 15 )$$

$$Δ {\hat{Q}}_{Y} ( τ \vert X ) = log ( 1 + {e}^{Δ {\hat{q}}_{Y} ( τ \vert X )} ) , \qquad \# ( 16 )$$

$$Δ {\hat{Q}}_{Y} ( τ \vert X ) = \{ \begin{matrix}max ( Δ {\hat{q}}_{Y} ( τ \vert X ) , 0 ) , Δ {\hat{q}}_{Y} ( τ \vert X ) > 0 \\ max ( Δ {\hat{q}}_{Y} ( τ \vert X ) , 0 ) + θ , Δ {\hat{q}}_{Y} ( τ \vert X ) \leq 0\end{matrix} , \qquad \# ( 17 )$$

where θ is a positive value to ensure that the obtained difference is greater than 0. Keeping the structure of the neural network unchanged, three different models can be obtained by replacing the loss function of MSF-DNQR with the above three equations, which are denoted as MSF-DNQR-SM, MSF-DNQR-SP, and MSF-DNQR-ReLU, respectively. The probabilistic wind speed forecasting results of the above three models and the proposed MSF-DNQR on two datasets are given in Table 3 and Table 4, respectively.

TABLE 3
Probabilistic wind speed forecasting with different activation
functions on Dataset A.

| PIN | Method | PICP | ACE | MPI | PINA | CWC | IS | PL |
|---|---|---|---|---|---|---|---|---|
| 85% | MSF-DNQR-SM | 0.878 | 0.028 | 2.983 | 0.1267 | 0.126 | −1.304 | 0.163 |
| | MSF-DNQR-SP | 0.898 | 0.048 | 4.701 | 0.1996 | 0.199 | −1.748 | 0.218 |
| | MSF-DNQR-Re | 0.858 | 0.008 | 2.752 | 0.1169 | 0.116 | −1.205 | 0.150 |
| | MSF-DNQR | 0.862 | 0.012 | 2.689 | 0.1142 | 0.114 | −1.183 | 0.148 |
| 90% | MSF-DNQR-SM | 0.925 | 0.025 | 3.679 | 0.1562 | 0.156 | −1.016 | 0.127 |
| | MSF-DNQR-SP | 0.963 | 0.063 | 5.703 | 0.2422 | 0.242 | −1.298 | 0.162 |
| | MSF-DNQR-Re | 0.933 | 0.033 | 3.599 | 0.1528 | 0.152 | −0.930 | 0.116 |
| | MSF-DNQR | 0.911 | 0.011 | 3.253 | 0.1382 | 0.138 | −0.907 | 0.113 |
| 95% | MSF-DNQR-SM | 0.972 | 0.022 | 5.302 | 0.2251 | 0.225 | −0.659 | 0.082 |
| | MSF-DNQR-SP | 0.971 | 0.021 | 6.669 | 0.2832 | 0.283 | −0.790 | 0.098 |
| | MSF-DNQR-Re | 0.944 | −0.005 | 4.129 | 0.1754 | 1.498 | −0.587 | 0.073 |
| | MSF-DNQR | 0.962 | 0.012 | 4.344 | 0.1845 | 0.184 | −0.569 | 0.071 |

TABLE 4
Probabilistic wind speed forecasting with different activation
functions on Dataset B.

| | PINMethod | PICP | ACE | MPI | PINA | CWC | IS | PL |
|---|---|---|---|---|---|---|---|---|
| 85% | MSF-DNQR-SM | 0.887 | 0.037 | 2.851 | 0.1414 | 0.141 | −1.226 | 0.153 |
| | MSF-DNQR-SP | 0.941 | 0.091 | 5.102 | 0.2531 | 0.253 | −1.723 | 0.215 |
| | MSF-DNQR-Re | 0.864 | 0.014 | 2.673 | 0.1326 | 0.132 | −1.172 | 0.146 |
| | MSF-DNQR | 0.857 | 0.007 | 2.537 | 0.1258 | 0.125 | −1.153 | 0.144 |
| 90% | MSF-DNQR-SM | 0.927 | 0.027 | 3.458 | 0.1715 | 0.171 | −0.950 | 0.118 |
| | MSF-DNQR-SP | 0.956 | 0.056 | 6.028 | 0.2990 | 0.299 | −1.363 | 0.170 |
| | MSF-DNQR-Re | 0.912 | 0.012 | 3.227 | 0.1601 | 0.160 | −0.890 | 0.111 |
| | MSF-DNQR | 0.906 | 0.006 | 3.071 | 0.1523 | 0.152 | −0.887 | 0.110 |
| 95% | MSF-DNQR-SM | 0.969 | 0.019 | 4.790 | 0.2376 | 0.237 | −0.612 | 0.076 |
| | MSF-DNQR-SP | 0.957 | 0.007 | 6.058 | 0.3005 | 0.300 | −0.761 | 0.095 |
| | MSF-DNQR-Re | 0.931 | 0.018 | 3.800 | 0.1885 | 2.723 | −0.572 | 0.071 |
| | MSF-DNQR | 0.955 | 0.005 | 4.079 | 0.2023 | 0.202 | −0.555 | 0.069 |

First, MSF-DNQR performs the best among all models. All PICPs satisfy the given confidence levels while the values of ACE, MPIW, PINAW, CWC, PL and the absolute values of IS are the smallest in most cases. Second, the performance of MSF-DNQR-ReLU is close to that of MSF-DNQR, but it lacks enough reliability because its PICPs are sometimes smaller than the preset PINCs. Third, MSF-DNQR-SM and MSF-DNQR-SP perform the worst. Although they guarantee the preset PINCs, the widths of PIs generated are too wide. Simultaneously, the comprehensive quality and accuracy of the generated PIs are not as good as MSF-DNQR in terms of CWC, IS and PI. Hence, it can be concluded that compared with the above three different strategies based on softmax, softplus and ReLU activation functions, the non-crossing quantile loss in MSF-DNQR, achieves the best performance.

The invention also provides a forecasting system that is constructed by the probabilistic wind speed forecasting method based on multi-scale information in the above embodiments. The system includes:

Data acquisition module. In this module, historical wind speed data are obtained and divided into a training set and a test set.

Model construction module. In this module, a neural network which includes an MSF extraction module and an attention-based LSTM module is constructed. The MSF extraction module is used to extract 1D feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting.

Loss function construction module. In this module, a quantile loss function is designed for training the neural network. First, determine the initial difference between the conditional quantiles at any two adjacent quantiles. Then, convert the initial difference into a set of positive differences of the conditional quantiles through the approximate absolute-value conversion. Finally, determine the forecasts of the conditional quantiles for the remaining quantiles based on the conditional quantiles and the difference between the conditional quantiles at the two adjacent quantiles, and then the loss value can be computed based on the quantile loss function.

Forecasting module. The neural network is trained with the training set, and then input the test set into the trained model to obtain the initial conditional quantile differences, which are converted to positive differences of the conditional quantiles through the approximate absolute-value conversion. By combining the conditional quantiles at two different quantiles, PIs at a certain confidence level can be obtained. Meanwhile, the continuous probability density curve can be estimated with KDE based on all the acquired discrete conditional quantiles.

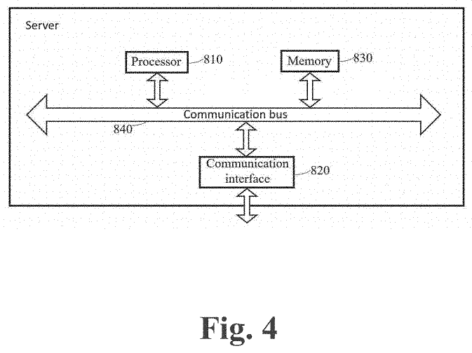

Based on the same conceive, the invention also provides a schematic picture of an entity structure. As shown in FIG. 4, the server includes a processor 810, a communication interface 820, a memory 830, and a communication bus 840. The processor 810, the communication interface 820, and the memory 830 communicate with each other through the communication bus 840. The processor 810 may call the logical instructions in the memory 830 to execute the steps of the multi-scale information-based probabilistic wind speed forecasting method as described in the above embodiments, which include:

Step S1: Obtain historical wind speed data and divide it into a training set and a test set.

Step S2: Construct the neural network, which includes the MSF extraction module and attention-based LSTM. The MSF extraction module is used to extract one-dimensional (1D) feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting.

Step S3: Design loss function for training the neural network. First, determine the initial difference between the conditional quantiles of any two adjacent quantiles. Then, convert the initial difference into a set of positive differences of conditional quantiles through the approximate absolute-value conversion. Finally, determine the forecasts of the conditional quantiles for the remaining quantiles based on the conditional quantiles and the difference between the conditional quantiles of the two adjacent quantiles, and then the loss value can be computed based on the quantile loss function.

Step S4: Train the neural network with the training set and then input the test set into the trained model to obtain the initial conditional quantile differences, which are converted to positive differences of the conditional quantiles through the approximate absolute-value conversion. By combining conditional quantiles at two different quantiles, PIs at a certain confidence level can be obtained. Meanwhile, the continuous probability density curve can be estimated with KDE based on all the acquired discrete conditional quantiles.

In addition, the above-mentioned logical instructions in the memory 830 can be implemented in the form of software functional units and sold or used as independent products, which can be stored in a computer readable storage medium. Based on this understanding, the part of the technical solution of the invention that contributes to the existing technology can be embodied in the form of a software product. The computer software product is stored in a storage medium and includes a number of instructions to enable a computer device (which may be a personal computer, a server, or a network device, etc.) to perform all or part of the steps of the methods described in all embodiments of this invention. The aforementioned storage media includes: U disk, mobile hard disk, read-only memory (ROM, Read-Only Memory), random access memory (RAM, Random Access Memory), magnetic disks or optical disks and other media that can store program codes.

Based on the same concept, the invention also provides a non-transitory computer-readable storage medium, which stores computer programs that include at least one piece of code. The code can be executed by the main control device to control the main control device to implement the steps of the multi-scale information-based probabilistic wind speed forecasting method as described in the foregoing embodiments, which include:

Step S1: Obtain historical wind speed data and divide it into a training set and a test set.

Step S2: Construct the neural network, which includes the MSF extraction module and attention-based LSTM. The MSF extraction module is used to extract one-dimensional (1D) feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting.

Step S3: Design loss function for training the neural network. First, determine the initial difference between the conditional quantiles of any two adjacent quantiles. Then, convert the initial difference into a set of positive differences of conditional quantiles through the approximate absolute-value conversion. Finally, determine the forecasts of the conditional quantiles for the remaining quantiles based on the conditional quantiles and the difference between the conditional quantiles of the two adjacent quantiles, and then the loss value can be computed based on the quantile loss function.

Step S4: Train the neural network with the training set, and then input the test set into the trained model to obtain the initial conditional quantile differences, which are converted to positive differences of the conditional quantiles through the approximate absolute-value conversion. By combining conditional quantiles at two different quantiles, PIs at a certain confidence level can be obtained. Meanwhile, the continuous probability density curve can be estimated with KDE based on all the acquired discrete conditional quantiles.

Based on the same technical conceive, the invention also provides a computer program, which is used to implement the above embodiments when the computer program is executed by the master control device.

The program may be stored in whole or in part on a storage medium packaged with the processor, and may also be stored in whole or in part in a memory not packaged with the processor.

Based on the same technical conceive, the invention further provides a processor, which is configured to implement the above method embodiment. The aforementioned processor may be a chip.

In summary, the invention provides a probabilistic wind speed forecasting method and system based on multi-scale information. First, a CNN model with multiple convolutional layers is employed for extracting MSFs. Then, an attention-based LSTM is utilized to extract temporal characteristics from the features at each scale and encode them into a low-dimensional feature vector. The difference between the conditional quantiles at adjacent quantiles is obtained with the proposed non-crossing quantile loss, and the estimates of all the conditional quantiles can be calculated by accumulating and subtracting. The proposed invention can extract sufficient MSFs from limited data, provide high-quality and reliable probabilistic forecasts, and solve the crossing problem of quantile-based models.

The various embodiments of the present invention can be arbitrarily combined to achieve different technical effects.

The above embodiments can be implemented by software, hardware, firmware, or any combination. When implemented by software, it can be implemented in the form of computer program products in whole or in part. The computer program products include one or more computer instructions. When the computer program instructions are loaded and executed on the computer, all or part of the processes or functions described in this application are generated. The computer may be a general-purpose computer, a special-purpose computer, a computer network, or other programmable devices. The computer instructions may be stored in, computer-readable storage medium, or transmitted from one computer-readable storage medium to another computer-readable storage medium. For example, the computer instructions may be transmitted from a website, computer, server, or data center to another website, computer, server or data center via wired (such as coaxial cable, optical fiber, digital subscriber line) or wireless (such as infrared, wireless, microwave, etc.). The computer-readable storage medium may be any available medium that can be accessed by a computer or a data storage device such as a server or a data center integrated with one or more available media. The usable medium may be a magnetic medium (for example, a floppy disk, a hard disk, and a magnetic tape), an optical, medium (for example, a DVD), or a semiconductor medium (for example, a solid-state disk).

A person of ordinary skill in the same research field can understand and achieve all or part of the process in the above-mentioned embodiments. The process can be completed by a computer program that instructs relevant hardware, and the program can be stored in a computer readable storage medium. The program can execute the processes of the methods in the foregoing embodiments. The aforementioned storage media includes: ROM or random storage RAM, magnetic disks or optical discs and other media that can store program codes.

Finally, it should be noted that the above embodiments are only used to illustrate the technical solutions of the invention, not to limit them. Although the invention has been described in detail with reference to the foregoing embodiments, those of ordinary skill in the same research field should understand that the technical solutions recorded in the foregoing embodiments are modified, or some of the technical features thereof are equivalently replaced. These modifications or replacements do not cause the essence of the corresponding technical solutions to deviate from the spirit and scope of the technical solutions of the embodiments of the present invention.

What is claimed is:

1. A probabilistic wind speed forecasting method based on multi-scale information. Its characteristics include:
Step S1: Obtain historical wind speed data and divide it into a training set and a test set;
Step S2: Construct the neural network, which includes the MSF extraction module and attention-based LSTM. The MSF extraction module is used to extract one-dimensional (1D) feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting;
Step S3: Design loss function for training the neural network. First, determine the initial difference between the conditional quantiles of any two adjacent quantiles. Then, convert the initial difference into a set of positive differences of conditional quantiles through the approximate absolute-value conversion. Finally, determine the forecasts of the conditional quantiles for the remaining quantiles based on the conditional quantiles and the difference between the conditional quantiles of the two adjacent quantiles, and then the loss value can be computed based on the quantile loss function;
Step S4: Train the neural network with the training set, and then input the test set into the trained model to obtain the initial conditional quantile differences, which are converted to positive differences of the conditional quantiles through the approximate absolute-value conversion. By combining conditional quantiles at two different quantiles, PIs at a certain confidence level can be obtained. Meanwhile, the continuous probability density curve can be estimated with KDE based on all the acquired discrete conditional quantiles.

2. According to the probabilistic wind speed forecasting method based on multi-scale information shown in claim 1, the Step S1 specifically includes:
Collect historical wind speed time series, and normalize them with:
$${x}_{normal} = \frac{x - {x}_{min}}{{x}_{max} - {x}_{min}} ,$$
where xₙₒᵣₘₐₗ is the normalized data, x represents the original wind speed series, and xₘₐₓ, xₘᵢₙ are the maximum and minimum, of x, respectively;
The wind speed data is divided into a training set and a test set according to a preset ratio, the training set is used for model training, and the test set is used for testing the forecasting performance of the model.

3. According to the probabilistic wind speed forecasting method based on multi-scale information shown in claim 1, the MSF extraction module depicted in step S2 includes three stacked 1D convolutional layers. Each convolutional layer contains multiple kernels. The convolutional operation is defined as follows:
yⱼ^{k}=ƒ(bⱼ^{k}+Σ_{h∈M}_{ⱼ} wₕⱼ^{k-1}*xₕ^{k-1}), where xₕ^{k-1} is the output of the h^{th} neuron at the (k−1)^{th} convolutional layer, Mⱼ is a set of input maps of the j^{th} neuron, bⱼ^{k} and yⱼ^{k} are the bias and output of the j^{th} neuron in the k^{th} convolutional layer, respectively, wₕⱼ^{k-1} is the weight matrix from the i^{th} neuron in the (k−1)^{th} convolutional layer to the j^{th} neuron in the k^{th} convolutional layer, ƒ(⋅) represents the activation function, and * denotes the convolution operation;
The 1D feature vectors generated by all the kernels of are concatenated in parallel to form a multi-dimensional feature subsequence. In this way, three subsequences {cⁱ}_{i=1,2,3} are obtained at this stage for each input.

4. According to the probabilistic wind speed forecasting method based on multi-scale information shown in claim 1, the attention-based. LSTM module depicted in step S2 is specifically used to:
For each subsequence cⁱ, first, LSTM is used to extract temporal feature hⁱ={h₁ⁱ, h₂ⁱ, . . . , h_{L}_{ᵢ}ⁱ}, in which hⁱ is the hidden state of all the units in the i^{th} LSTM, Lᵢ denotes the number of the units. Then, convert hⁱ to h^{i′}={h_{i′}, h₂^{i′}, . . . h_{L}_{ᵢ}^{i′}} through the fully connected layer. Finally, h^{i″}={h_{i″}, h₂^{i″}, . . . h_{L}_{ᵢ}^{i″}} is obtained by adding h_{L}_{ᵢ}ⁱ to h^{i′}:
h^{i″}=h^{i′}+h_{L}_{ᵢ}ⁱ,
where hᵢ^{i″} is the new obtained feature vector, h^{i′} is the feature vector generated by the fully connected operation, and h_{L}_{ᵢ}ⁱ is the hidden state of the last unit in the i^{th} LSTM. Using the attention mechanism to assign weights for feature vectors in h^{i″}:
$${a}_{l}^{i} = \frac{exp ( {h}_{{L}_{i}}^{iT} {h}_{l}^{i ″} )}{{\sum }_{k = 1}^{{L}_{i}} exp ( {h}_{{L}_{i}}^{iT} {h}_{k}^{i ″} )} ,$$
in which hᵢ^{i″} and hₖ^{i″} are the l^{th} and k^{th} feature vector in h_{i″}, and aₗⁱ represents the attention probability for hᵢ^{i″}. Afterwards, a low-dimensional feature vector is obtained by weighting, the feature vectors in h^{i″} according to the derived attention probabilities:
$${v}^{i} = {\sum }_{l = 1}^{{L}_{i}} {a}_{l}^{i} {h}_{l}^{i ″} ,$$
where vⁱ represents the obtained feature vector for cⁱ. The final feature vector V is obtained by concatenating {vⁱ}_{i=1,2,3} together, which is used to generate forecasts through the fully connected layers.

5. According to the probabilistic wind speed forecasting method based on multi-scale information shown in claim 2, the quantile, loss function is introduced as follows:
Q_{Y}(τ|X)=ƒ(X,β(τ)),
where Q_{Y}(τ|X) is the estimation at quantile τ with the input X=(x₁, x₂, . . . , x_{N}), the target variables are Y=(y₁, y₂, . . . , y_{N}), ƒ(⋅) is a nonlinear function, and β(τ) represents the regression coefficients, which can be estimated by minimizing the loss function as follows:
$$\hat{β} ( τ ) = {min}_{β ( τ )} {\sum }_{i = 1}^{N} φ ( {y}_{i} , {Q}_{{y}_{i}} ( τ \vert {x}_{i} ) ) ,$$
where \hat{β}(τ) is the estimate of β(τ), N is the number of input samples, yᵢ is the targeted value that corresponds to the input xᵢ, Q_{y}_{ᵢ}(τ|xᵢ) is the conditional quantile at quantile τ, φ(⋅) is the quantile loss:
$$φ ( {y}_{i} , {Q}_{{y}_{i}} ( τ \vert {x}_{i} ) ) = \{ \begin{matrix}τ ( {y}_{i} - {Q}_{{y}_{i}} ( τ \vert {x}_{i} ) ) & {y}_{i} \geq {Q}_{{y}_{i}} ( τ \vert {x}_{i} ) \\ ( τ - 1 ) ( {y}_{i} - {Q}_{{y}_{i}} ( τ \vert {x}_{i} ) ) & {y}_{i} < {Q}_{{y}_{i}} ( τ \vert {x}_{i} )\end{matrix} .$$

6. According to the probabilistic wind speed forecasting method based on multi-scale information shown in claim 5, the output of the conditional quantile \hat{Q}_{Y}(τ|X) includes the conditional quantile \hat{Q}_{Y}(τₖ_{₀}|X) at the middle quantile τₖ_{₀} and the initial difference between the conditional quantiles at any two adjacent quantiles Δ\hat{q}_{Y}(τ|X);
Supposing there are K quantiles τ={τₖ}_{k=1,2, . . . , K}, 0<τ₁<τ₂< . . . <τₖ_{₀}< . . . <τ_{K}<1, τₖ_{₀}=0.5,
$${\hat{Q}}_{Y} ( τ \vert X ) = {\{ {\hat{Q}}_{{y}_{i}} ( {τ}_{k} \vert {x}_{i} ) \}}_{k = 1 , 2 , … , {K}^{′}}^{i = 1 , 2 , … , N}$$
$${\hat{Q}}_{Y} ( {τ}_{{k}_{0}} \vert X ) = {\{ {\hat{Q}}_{{y}_{i}} ( {τ}_{{k}_{0}} \vert {x}_{i} ) \}}_{i = 1 , 2 , … , {N}^{′}}$$
$$Δ {\hat{q}}_{Y} ( τ \vert X ) = {\{ Δ {\hat{q}}_{{y}_{i}} ( {τ}_{k} \vert {x}_{i} ) \}}_{k = 1 , 2 , … , K - 1}^{i = 1 , 2 , … , N} .$$
A set of positive differences is obtained through the approximate absolute-value conversion with Δ\hat{q}_{Y}(τ|X), whose calculation is given by:
$$Δ {\hat{Q}}_{Y} ( τ \vert X ) = \{ \begin{matrix}Δ {\hat{q}}_{Y} ( τ \vert X ) & Δ {\hat{q}}_{Y} ( τ \vert X ) > 0 \\ θ & Δ {\hat{q}}_{Y} ( τ \vert X ) = 0 , \# \\ - Δ {\hat{q}}_{Y} ( τ \vert X ) & Δ {\hat{q}}_{Y} ( τ \vert X ) < 0\end{matrix}$$
where θ is a positive value,
$$Δ {\hat{Q}}_{Y} ( τ \vert X ) = {\{ Δ {\hat{Q}}_{{y}_{i}} ( {τ}_{k} \vert {x}_{i} ) \}}_{k = 1 , 2 , … , K - 1}^{i = 1 , 2 , … , N}$$
is the obtained positive difference between two adjacent conditional quantiles, and Δ\hat{Q}_{y}_{ᵢ}(τₖ|xᵢ)=\hat{Q}_{y}_{ᵢ}(τₖ₊₁|xᵢ)−\hat{Q}_{y}_{ᵢ}(τₖ|xᵢ);
Based on the obtained conditional quantile \hat{Q}_{Y}(τₖ_{₀}|X) and the conditional quantile difference Δ\hat{Q}_{Y}(τ|X), the estimates of all the conditional quantiles can be calculated by accumulating and subtracting from \hat{Q}_{Y}(τₖ_{₀}|X):
$${\hat{Q}}_{Y} ( {τ}_{k} \vert X ) = \{ \begin{matrix}{\hat{Q}}_{Y} ( {τ}_{{k}_{0}} \vert X ) + {\sum }_{j = {k}_{0}}^{k - 1} Δ {\hat{Q}}_{y} ( {τ}_{j} \vert k > {k}_{0} \\ {\hat{Q}}_{Y} ( {τ}_{{k}_{0}} \vert X ) - {\sum }_{j = k}^{{k}_{0} - 1} Δ {\hat{Q}}_{Y} ( {τ}_{j} \vert X ) k < {k}_{0}\end{matrix} ,$$
where \hat{Q}_{Y}(τₖ|X) is the estimate at quantile τₖ;
Finally, the total quantile loss used for model training can be computed as:
$$L = \frac{1}{N} {\sum }_{i = 1}^{N} {\sum }_{k = 1}^{K} φ ( {y}_{i} , {\hat{Q}}_{{y}_{i}} ( {τ}_{k} \vert {x}_{i} ) ) ,$$
where L represents the value of loss.

7. According to the probabilistic wind speed prediction method based on multi-scale information shown in claim 6, the probability density curve is estimated by:
$$\hat{f} ( z ) = \frac{1}{BK} {\sum }_{k = 1}^{K} {K}_{E} ( \frac{{\hat{Q}}_{{y}_{i}} ( {τ}_{k} \vert {x}_{i} ) - z}{B} ) ,$$
$${K}_{E} ( α ) = \{ \begin{matrix}\frac{3}{4} ( 1 - {α}^{2} ) & α ∈ [ - 1 , 1 ] \\ 0 & α ∉ [ - 1 , 1 ]\end{matrix} ,$$
in which ƒ(z) is the obtained PDF, B is the bandwidth, and K_{E}(α) is the Epanechnikov kernel function.

8. A probabilistic wind speed forecasting system based on multi-scale information contains:
Data acquisition module. In this module, historical wind speed data are obtained and divided into a training set and a test set;
Model construction module. In this module, a neural network which includes an MSF extraction module and an attention-based LSTM module is constructed. The MSF extraction module is used to extract 1D feature vectors from input vector, which are then concatenated in parallel to form multiple sets of feature subsequences at different levels. The attention-based LSTM module is used to extract temporal information from the obtained feature subsequences. The local information in the temporal features is weighted to form a low-dimensional feature vector to characterize the above feature subsequence. Finally, all low-dimensional feature vectors are concatenated to form a predictive feature vector for forecasting;
Loss function construction module. In this module, a quantile loss function is designed for training the neural network. First, determine the initial difference between the conditional quantiles at any two adjacent quantiles. Then, convert the initial difference into a set of positive differences of the conditional quantiles through the approximate absolute-value conversion. Finally, determine the forecasts of the conditional quantiles for the remaining quantiles based on the conditional quantiles and the difference between the conditional quantiles at the two adjacent quantiles, and then the loss value can be computed based on the quantile loss function;
Forecasting module. The neural network is trained with the training set, and then input the test set into the trained model to obtain the initial conditional quantile differences, which are converted to positive differences of the conditional quantiles through the approximate absolute-value conversion. By combining the conditional quantiles at two different quantiles, PIs at a certain confidence level can be obtained. Meanwhile, the continuous probability density curve can be estimated with KDE based on all the acquired discrete conditional quantiles.
